(19) United States
(12) Patent Application Publication
(10) Pub. No.: US 2025/0260181 A1
(43) Pub. Date: Aug. 14, 2025

(54) GROUND CABLE MONITORING SYSTEM AND METHOD OF USING

(71) Applicant: CBS ArcSafe, Inc., Denton, TX (US)

(72) Inventor: Finley Lee Ledbetter, Argyle, TX (US)

(73) Assignee: CBS ArcSafe, Inc., Denton, TX (US)

(21) Appl. No.: 19/052,145

(22) Filed: Feb. 12, 2025

Related U.S. Application Data
(60) Provisional application No. 63/552,976, filed on Feb. 13, 2024.

(51) Int. Cl. H01R 4/40; G01R 31/08; H01R 4/66; H01R 11/26

(52) U.S. Cl. CPC H01R 4/40; G01R 31/083; H01R 4/66; H01R 11/26

(57) ABSTRACT

A smart grounding clamp system includes a grounding clamp, the grounding clamp having a clamp member and a cable member. The smart grounding clamp monitoring system further includes a sensor module mechanically coupled to the grounding clamp and having at least one sensor configured to sense an environmental condition of the grounding clamp and a communication module communicatively coupled with the at least one sensor. The smart grounding clamp monitoring system also includes a base station positioned remotely from the grounding clamp and communicatively coupled to the communication module.

### CROSS-REFERENCE TO RELATED APPLICATIONS

This patent application is a Non-Provisional Application that claims priority to and the benefit of U.S. Provisional Patent Application No. 63/552,976, filed on Feb. 13, 2024, entitled “Electrical Cable Monitoring System and Method of Using,” the entire contents of which is incorporated herein by reference for all purposes.

### BACKGROUND

In an industrial setting, the dangers associated with grounding clamps being inadvertently moved, disconnected, or being inadvertently connected to equipment when the equipment is energized without proper communication and coordination can be severe. Grounding clamps play a crucial role in dissipating electrical charges and ensuring the safety of both personnel and equipment. Routinely, one crew of workers will be responsible for connecting the grounding clamps to a piece of equipment to initiate some type of work on the equipment, and a separate crew of workers finishes the work later in the day. In such situations, it is common for one or more clamps to be inadvertently left connected to equipment when the second crew of workers finishes the work and energizes the equipment, resulting in severe damage to the equipment. In other situations, one crew completes the entire job from start to finish, but through fatigue or otherwise, they mistakenly believe that all clamps have been removed when one or more clamps were left connected. When these clamps are moved, disconnected, or left connected when equipment is energized without informing all individuals involved in the work it can leave equipment and people vulnerable to electrical hazards. Without a reliable ground, even a seemingly routine task can turn into a high-risk operation, with the potential for electrostatic discharge, electrical shocks, or even fires.

One significant danger of improperly handling grounding clamps is the risk of electrostatic discharge. When equipment is not adequately grounded, static electricity can build up on surfaces and components. If this charge is suddenly released, it can result in sparks or electrostatic discharge events. These sparks can ignite flammable materials, damage sensitive electronics, or, in certain environments, cause explosions. In addition, electrostatic discharge can pose a risk to personnel, leading to electrical shocks or injuries. When grounding clamps are inadvertently moved or disconnected without proper communication, the risk of electrostatic discharge significantly increases, putting both equipment and individuals in harm's way.

Another critical danger arises from the potential for uncontrolled electrical surges and overloads when grounding clamps are mishandled. Proper grounding helps dissipate excess electrical charges to the ground, preventing the buildup of voltage in a circuit or equipment. If a clamp is inadvertently moved or disconnected during work, the protective grounding path is interrupted, leaving the system vulnerable to voltage spikes. These surges can damage sensitive equipment, disrupt processes, and pose a risk to personnel. Without proper communication and coordination in such situations, the consequences can be dire, potentially leading to costly equipment failures, production delays, and, most importantly, jeopardizing the safety of workers within the industrial environment.

### SUMMARY OF THE INVENTION

According to a first aspect a smart grounding clamp system includes a grounding clamp, the grounding clamp having a clamp member and a cable member. The smart grounding clamp system also includes a sensor module mechanically coupled to the grounding clamp and having at least one sensor configured to sense an environmental condition of the grounding clamp and a communication module communicatively coupled with the at least one sensor. The smart grounding clamp system further includes a base station positioned remotely from the grounding clamp and communicatively coupled to the communication module.

According to many embodiments, the at least one sensor is an accelerometer configured to sense a change in the position of the grounding clamp.

In some embodiments, the at least one sensor is a partial discharge sensor.

According to other embodiments, the at least one sensor is an infrared sensor configured to sense a movement.

In other embodiments, the smart grounding clamp system further includes a camera sensor configured to capture at least one photograph in response to the infrared sensor sensing the movement.

According to some other embodiments, the smart grounding clamp system further includes a storage module communicatively coupled to the camera sensor and is configured to store at least one photograph captured by the camera sensor.

In many embodiments, the base station further includes an external communication module configured communicate with an external device.

According to many other embodiments, the grounding clamp is a plurality of grounding clamps and the communication module of a first grounding clamp of the plurality of grounding clamps can communicate with the communication module of a second grounding clamp of the plurality of grounding clamps.

In some embodiments, the communication module is further configured to communicate with an external device.

According to some embodiments, the base station further includes a display configured to display a status of the grounding clamp.

According to a second aspect a smart grounding clamp system includes a plurality of grounding clamps, the plurality of grounding clamps each having at least one clamp member and a cable member. The smart grounding clamp system further includes a sensor module mechanically coupled to the at least one clamp member and having at least one sensor, a communication module communicatively coupled with the at least one sensor, and a power module configured to provide power to the at least one sensor and the communications module. The smart grounding clamp system also includes a base station positioned remotely from the plurality of grounding clamps and communicatively coupled to each of the communication modules.

According to many embodiments, the power module is a replaceable battery.

In some embodiments, the sensor module is positioned within a waterproof enclosure.

According to some other embodiments, the at least one sensor is an accelerometer configured to sense a change in the position of the grounding clamp.

In many embodiments, the at least one sensor is an infrared sensor configured to sense a movement near the infrared sensor.

According to some embodiments, the at least one sensor is a partial discharge sensor.

According to a third aspect a method of manufacturing a smart grounding clamp system, includes the step of providing a grounding clamp, the grounding clamp having a clamp member and a cable member. The method further includes the step of mechanically coupling a sensor module to the grounding clamp, the sensor module having at least one sensor configured to sense an environmental condition of the grounding clamp and a communication module communicatively coupled with the at least one sensor. The method finally includes the step of providing a base station configured to be positioned remotely from the grounding clamp and communicatively coupled to the communication module.

According to many embodiments, the at least one sensor is an accelerometer configured to sense a change in the position of the grounding clamp.

In many embodiments, the at least one sensor is an infrared sensor configured to sense a movement near the infrared sensor.

According to some embodiments, the at least one sensor is a partial discharge sensor.

### BRIEF DESCRIPTION OF THE DRAWINGS

The disclosure will become more fully understood from the following detailed description, taken in conjunction with the accompanying figures, wherein like reference numerals refer to like elements, in which:

FIG. 1 is a diagram of the ground clamp monitoring system.

FIGS. 2A-2B depict a top perspective view of an embodiment of a ground clamp and a multi-clamp ground clamp respectively.

FIG. 3 depicts a block diagram of a sensor module.

FIG. 4 depicts a front perspective view of a base station.

FIG. 5 depicts a block diagram of a central communications module.

FIG. 6 depicts a front side perspective view of a lock box.

FIG. 7 depicts a block flow diagram of a method of manufacturing a ground clamp monitoring system.

FIG. 8 depicts a block flow diagram of a method of operating a ground clamp monitoring system.

The drawings are not necessarily to scale and certain features may be shown exaggerated in scale or in somewhat schematic form in the interest of clarity and conciseness.

### DETAILED DESCRIPTION

Grounding clamps, shorting straps, and other devices or components for transmitting electrical current to ground aid to mitigate risks in the workplace and knowing which grounding camps 10 are still in service and which are not are important for the operations and safety of a work site. Moreover, of the grounding clamps 10 that are in service, knowing which ones may have been disconnected and may require an inspection is similarly important for the safety and operability of the work site. As multiple grounding clamps 10 may be connected and in service across a work site, having the ability to check at a single location, such as a base station 12, which grounding clamps 10 are still connected and which may not be and thus may require inspection is valuable to increasing the efficiency of the work site. To increase the probability that a base station 12 will be in range of all of the grounding clamps 10 at the work site, the grounding clamps 10 are capable of forming a mesh network such that each grounding clamp can receive the messages from another grounding clamp 10 and subsequently pass that message either directly to the base station 12 or to another grounding clamp 10 that is within range of the base station 12. In this manner, a single base station 12 is capable of accounting for grounding clamps 10 that the base station 12 is not within range of.

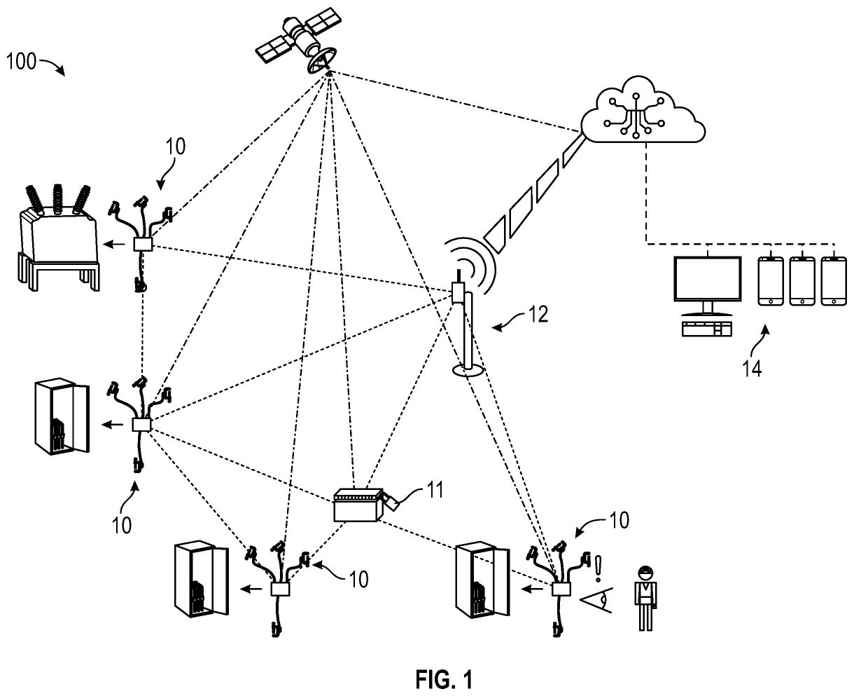

Embodiments disclosed herein describe a ground clamp monitoring system 100 and methods for manufacturing and operating the same. As shown in FIG. 1, a ground clamp monitoring system 100 includes at least one ground clamp 10 coupled to a clamp sensor module 20. The clamp sensor module 20 is configured to sense or detect various environmental conditions that relate to a status of the ground clamp 10 and communicate the same to a base station 12. The base station 12 is similarly configured to communicate the status of the ground clamp 10 and/or the environmental condition that relates to the status of the ground clamp 10 to an external device 14 directly or to an external server such that the status or environmental condition can be accessed by an external device 14.

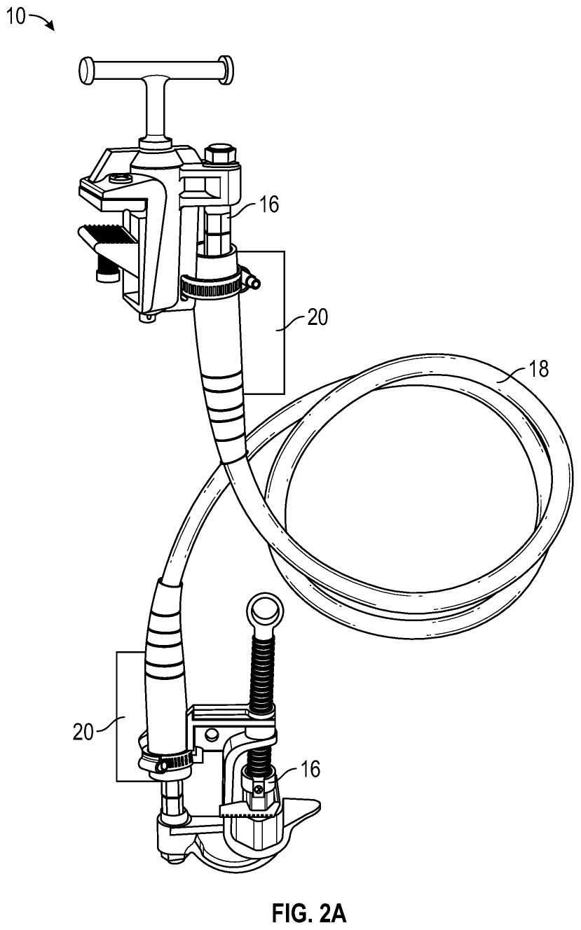

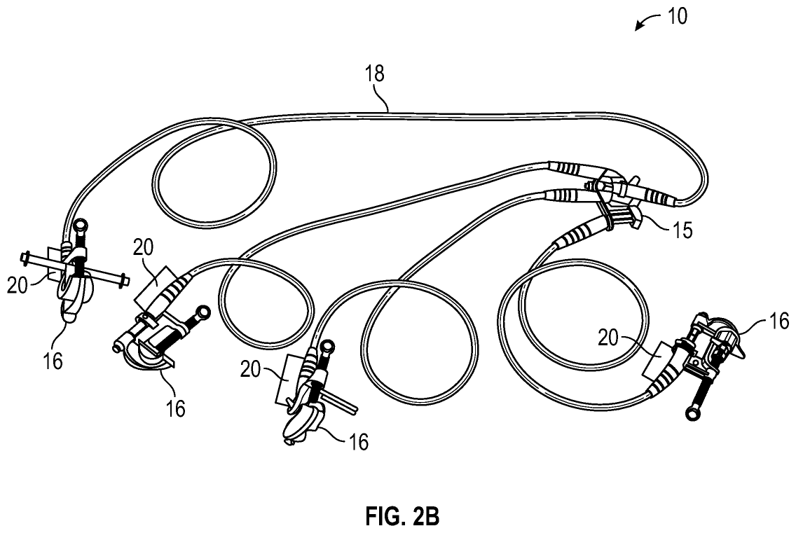

Reference is now made to FIGS. 2A-2B, which depict embodiments of a ground clamp 10 and multi-clamp ground clamp 40. The ground clamp 10 includes a clamp portion or clamp member 16 electrically coupled to a cable portion or cable member 18 on either end of the cable member 18. In use, one cable member 16 will be clamped onto or otherwise electrically coupled to a source of electrical ground while the clamp member 16 that is positioned about the opposed end of the cable member 18 will be clamped onto or otherwise electrically coupled to a piece of machinery that is being worked on. Each clamp member 16 is also mechanically coupled to a clamp sensor module 20, which will be discussed in further detail below. As shown in FIG. 2B, a multi-clamp ground clamp 40 is functionally similar to the ground clamp 10 with the difference being that the multi-clamp ground clamp 40 can clamp or electrically couple multiple pieces of machinery, or multiple pieces of the same piece of machinery, to a single ground point. The multi-clamp ground clamp 40 includes a plurality of cable members 18 that are coupled together at the ground plate 15 on an end of the cable member 18 and having a respective clamp member 16 coupled to the opposed end of the cable member 18. It should be understood, that while the clamp sensor module 20 is presently depicted as being mechanically coupled to the clamp member 16, other embodiments are also envisioned. For example, the clamp sensor module 20 may be mechanically coupled to the cable member 18 or any other suitable or desirable portion of the clamp member 10.

It should be understood, that while cable member 18 is presently depicted as a rounded cable, characterized by multiple strands of wire twisted together, providing flexibility and adaptability for various applications, other configurations are also envisioned. For example, cable member 18 can be a flat stranded cables or straps, which consist of wide, flat conductors, offering an expansive contact area suitable for grounding large equipment. As another example, cable member 18 can be a braided cable which is composed of woven or braided strands, combining flexibility with enhanced conductivity. As another example, cable member 18 can be a tape or ribbon cable which features a flat, ribbon-like structure, catering to low-profile design requirements or environments with spatial limitations. As yet another example, cable member 18 can be a bus bar which is a rigid conductor in the form of a bar or strip and well-suited for grounding in electrical panels, the bus bars may be formed of copper, aluminum, or any other suitable or desirable material. As another example, cable member 18 can be a spiral or helical cable which exhibits a helical or spiral configuration, facilitating flexibility and simplifying installation. As another example, cable member 18 can be any suitable or desirable shape for electrical grounding or otherwise transmitting electrical current or voltage therethrough.

Ground clamp 10 may also be configured as or referred to as bonding clamps, grounding connectors, or earthing clamps, may be known by various names such as grounding straps, shorting straps, shorting clips, or equipotential bonding clamps. Other terms and configurations include grounding latches, cable bonding clamps, and static grounding clamps. Ground clamp 10 may also be configured as or referred to as earth clamps, grounding bridges, or strap clamps, emphasizing their role in establishing a connection between electrical equipment and the ground for safety and operational purposes. The terms used may vary regionally or within specific industries, reflecting preferences, standards, and the nature of the application.

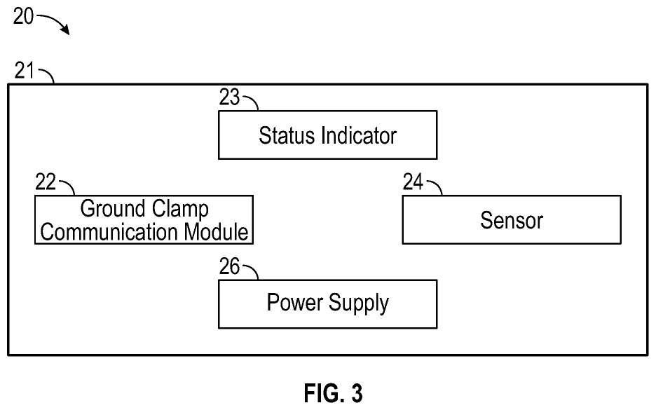

Reference is now made to FIG. 3, which depicts an embodiment of a clamp sensor module 20. As shown, a clamp sensor module 20 includes an enclosure 21, a clamp communications module 22, a sensor 24 and a clamp power supply 26. The enclosure 21 is sized and shaped to contain the clamp communications module 22, the sensor 24 and the clamp power supply 26 in the interior of the enclosure 21. The enclosure 21 is also configured to be generally weather-tight such that the ground clamp 10 can operate in outdoor environments largely unimpeded. In many embodiments, the enclosure 21 is an intrinsically safe enclosure such that it satisfies class 1 division 1 ratings for enclosures under the National Electrical Code (“NEC”) or other rating such as NEC class 1 division 2 or other suitable ratings for electrical enclosures operating in environments where ignitable hydrocarbons or other substances may be present. In other embodiments, the enclosure 21 is fully waterproof and submersible such that the enclosure can be submerged in puddles or other bodies of water without allowing for an ingress of water into the interior of the enclosure 21.

In many embodiments, the sensor module 20 is configured to be a retrofit application that can be fitted to grounding clamps that previously did not include a sensor module 20. In such embodiments, the enclosure 21 can include mounting points to facilitate mounting of the enclosure 21 to a component of a ground clamp 10 or multi-clamp ground clamp 40 that was not designed or manufactured to facilitate the mounting of the enclosure thereto. Such mounting of the enclosure 21 can be accomplished with one or more zip ties, hook and loop straps, or any other form of suitable permanent or temporary fastening system or combination of fastening systems.

With continued reference to FIG. 3, the sensor 24 is positioned within the interior of the enclosure 21 and is configured to sense an environmental condition that relates to the status of the ground clamp 10. The sensor 24 can be a movement sensor, such as an accelerometer, configured to sense if the ground clamp 10 has been moved since it was placed in service. The sensor 24 can be a position or location sensor, such as GPS receiver, configured to sense what is the position of the ground clamp 10 or if the ground clamp 10 has changed its position since it was placed in service. In implementations that utilize a GPS receiver sensor 24, to save or conserve power in the power supply 26, the location of the ground clamp 10 can be set to only update its location once a day. It should be understood that the GPS receiver sensor 24 can be configured to update the location of the ground clamp 10 once a shift, once a week, on demand, or any other suitable or desirable time period between location updates. A user can also request that the GPS receiver sensor 24 update the location of the ground clamp remotely from the external device 14 or the base station 12. The location data provided by the GPS receiver sensor 24 can be accessed at the base station 12 or remotely from external device 14. Knowing the location of the ground clamp 10 can aid in loss prevention and asset recovery operations in the event that a ground clamp 10 is lost or stolen. in some embodiments, the sensor 24 can be a Radio-Frequency Identification (“RFID”) tag. The RFID sensor 24 can be a passive RFID sensor 24, such that it is not electrically coupled to the power source 26, or an active RFID sensor 24 that is electrically coupled to and draws power from the power source 26. For implementations that utilize RFID sensors 24, a user can enter the work area with a RFID reader and be notified of any and all ground clamps 10 still present in the area.

The sensor 24 can be a visual sensor, such as a camera configured to capture still or static photographs or a video-camera configured to capture video. The sensor 24 can be a humidity or moisture sensor. The sensor 24 can also be an infrared motion sensor, or other motion sensor, configured to detect if there is motion in the vicinity of the ground clamp 10. The sensor 24 can also be a temperature sensor, such as a thermocouple, configured to sense or detect changes in the temperature about the proximity of the sensor 24, such as a fire, controlled or uncontrolled ignition, or other change in temperature. The sensor 24 can also be a combination of sensors such as a camera coupled to an infrared motion sensor in a manner such that when the infrared motion sensor senses a motion in the vicinity of the ground clamp 10, the infrared motion sensor causes the camera to capture a picture or photograph of the person or thing that is moving in the vicinity of the ground clamp 10. In many embodiments that utilize a visual sensor 24, the photograph or video clip captured can be processed through facial recognition process to determine or recognize the individual in the photograph or video clip. Such facial recognition processes can aid in the prevention of theft, vandalism, both, and other undesirable acts committed to the ground clamp 10. The facial recognition processes can be performed by the base station 12 or on the external device 14.

The ground clamp 10 status relates to its physical position and/or connection two pieces of machinery as the ground clamp 10 is deployed in the field. For example, a ground clamp 10 that is not in service or otherwise not connected to any piece of machinery or ground may have a status of “out of service,” while a ground clamp 10 that was recently put into service and has not moved or has been otherwise disturbed since it was put into service may have a status of “in service.” If the sensor 24 senses or detects that the ground clamp 10 may have been moved, jostled, disturbed, had its position changed, or has sensed movement in in its vicinity, or any other combination of change and the ground clamp's 10 environmental conditions, the status may change to “verify if still in service.” it should be understood that while only three different statuses are discussed here other statuses are also envisioned, for example the status may be “small movement detected,” or “small position change detected,” or “partial discharge detected.” In many embodiments, the status relates to the environmental condition sensed by sensor 24.

With continued reference to FIG. 3, the status indicator 23 can be a visual indicator such as an LED light that is configured to flash or illuminate a certain color or in a certain pattern when the status of the ground clamp 10 changes. The status indicator 23 can also be an audio indicator such as a speaker configured to provide an audible alarm when the status of the ground clamp 10 changes. In many embodiments, the status indicator 23 can include both a visual indication component and an audible indication component. The status indicator 23 is communicatively coupled to the sensor 24 such that when the sensor 24 senses or detects a change in the status of the ground clamp 10, the status indicator 23 can provide the appropriate status indication. The status indicator 23 can also be communicatively coupled to the clamp communications module 22 such that the status indicator 21 can be controlled or adjusted from the base station 12. For example, if the status indicator 23 is providing a visual indication of a blinking LED light, a user can also activate the audible indication remotely from the external device 14 or the base station 12. Similarly, if the status indicator 23 is providing an indication (visual, audible, or otherwise), the base station 12 can clear or silence the status indicator 21 such that no indication is provided.

The clamp communications module 22 is communicatively coupled to the sensor 24 and configured to primarily communicate with the central communications module 30 of the base station 12. In this manner, the clamp communications module 22 will update the central communications module 30 with the status of the ground clamp 10 on regular intervals such as once every hour, once every day, or any other suitable interval. The clamp communications module 22 can also be configured to update the central communications module 30 with the status of the ground clamp 10 anytime that the sensor 24 senses an environmental condition that may alter or change the status of the ground clamp 10 or anytime a user requests an update at the base station 12 or through an external device 14.

In some embodiments, the clamp communications module 22 may be out of range and not able to communicate directly with the central communications module 30. In such embodiments, the clamp communications module may send its update to another clamp communications module 22 of a separate ground clamp 10 that is still in range. In this manner, the ground clamps 10 can create a mesh network with one another such that so long as one ground clamp 10 is within communication range of the base station 12 (such that the clamp communications module 22 can't communicate with the local communications module 34), all communications from a plurality of ground clamps 10 can be routed through other surrounding ground clamps 10 to provide the status update to the local communications module 34 of the base station 12. This mesh network can also act in the reverse such that over the air updates or other communications originating from the local communications module 34 can be sent either directly to the communications module 22, if it is in range of the local communications module 34, or routed through the mesh network created by a plurality of communications modules 22. In this manner, all ground clamps 10 receive the update, message, or other communication from the local communications module 34. In many embodiments, the clamp communications module 22 is a radio transceiver configured for transmitting and receiving data according to various communication protocols such as Wi-Fi, Bluetooth, Zigbee, or any other suitable wireless communications protocol. As shown in FIG. 1, the clamp communications module 22 can also be configured to communicate directly with the external server or external device 14 if the clamp communications module 22 is in range of a compatible internet connection.

With continued reference to FIG. 3, the power supply 26 is positioned within the enclosure 21 and is electrically coupled or otherwise configured to provide electrical power to both the communications module 22 and sensor 24. The power supply 26 can be standard batteries of any suitable size such as, AA batteries, AAA batteries, cordless tool batteries, or any other suitable battery size. In other embodiments, the power supply 26 is electrically coupled to an external battery charger or other power source such as a solar panel to ensure that the power supply 26 of the sensor module 20 does not prematurely run out of power.

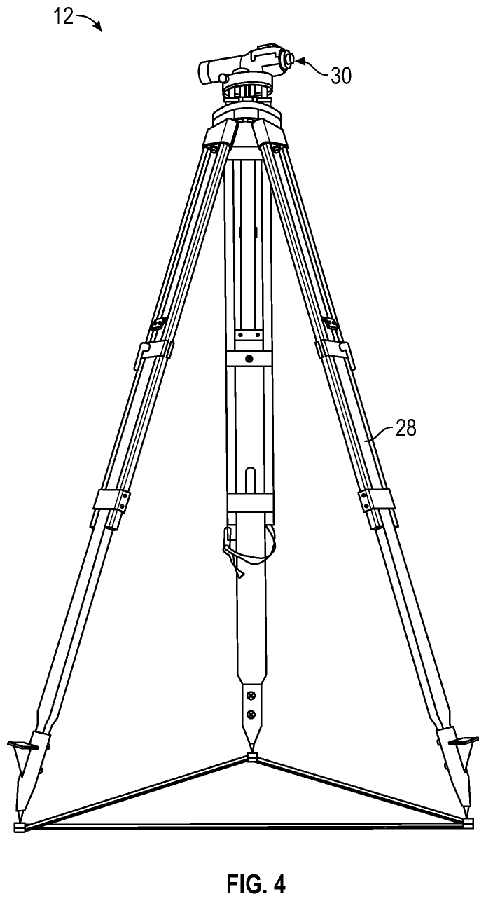

Reference is now made to FIG. 4, which depicts a front perspective view of an embodiment of a base station 12. A base station 12 includes a base member 28 and a central communications module 30. The base station 12 is generally positioned remotely from the ground clamps 10 in the system in a location where the central communications module 30 can send and receive a signal through a wireless or wired data connection. The central communications module 30 of the base station 12 is configured to receive communications from the various communication modules 22 of each respective ground clamp 10 regarding the status of the respective ground clamp 10 or data gathered by or sensed by the respective sensor 24. It should be understood, that while the base member 28 is depicted as a tri-pod in FIG. 4, alternate embodiments are also envisioned. For example, the base member 28 can be a flat plate with a central rod or pole extending from the plate, or any other configuration that suitably supports the central communications module 30.

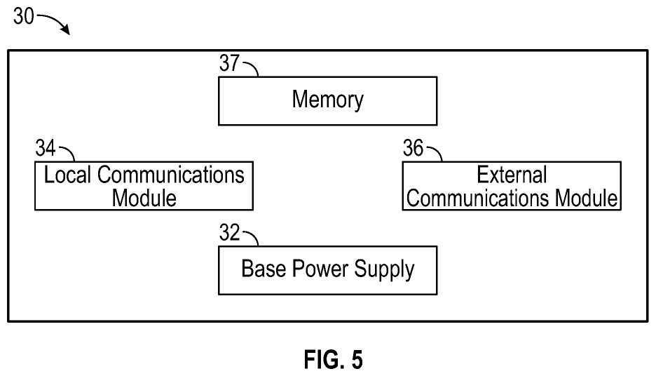

Reference is now made to FIG. 5, Which depicts a central communications module 30. The central communications module 30 includes a local communications module 32, an external communications module 34, a base power supply 36, and a memory 37. The local communications module 32 is configured to communicate with, receive status updates from, send over the air upgrades, or any other suitable information to each of the ground clamp communication modules 22. The local communications module 32 is configured to monitor the mesh network created by the plurality of ground clamps 10 and their respective ground clamp communication modules 22. If the local communications module 32 detects or recognizes a fault or problem with one or more of the ground clamps 10 that are affecting the mesh network, then the local communications module 32 can send an alert to the external communications module 34 to provide the alert directly to the external device 14. The alert can also be shown or displayed on the central communications module 30 by a visual indicator such as a light or other visual indicator indicating that a fault has been detected by blinking, illuminating a different color such as red, or any other suitable visual indication.

The external communications module 36 is communicatively coupled to the local communications module 34 and is electrically coupled or otherwise draws power from the base power supply 32. The external communications module 36 is configured to communicate with or otherwise update an external server or external device 14 with the current status or recent change in status of the ground clamp 10. From the external device 14, a user can view the current status of all of the ground clamps 10 that are connected to a single base station 12 without having to go out and physically inspect the ground clamp 10 to ensure that it is still properly in service or is out of service. Through the external device 14, a user can view and update the status of the ground clamps 10 remotely. It should be understood that the external device 14 can be a smartphone, tablet, laptop computer, desktop computer, or any other device configured to communicate with the external communications module 36 or receive updates from the external communications module 36 via the internet. As such, a user can access the status of any ground clamp 10 that is connected to the internet or external server, directly through the clamp communications module 22 or indirectly through the base station 12, from anywhere in the world that the external device 14 can connect to the internet. For example, a user can access the status of a particular grouping of ground clamps 10 from an external device 14, such as a laptop, within an office building located proximate to the work area where the ground clamps 10 are being utilized. As another example, the user can access the status of a particular grouping of ground clamps 10 from an external device 14, such as a smartphone, while attending a trade show located hundreds of miles from the work area where the ground clamps 10 are being utilized.

The memory 37 is communicatively coupled to the local communications module 34 and the external communications module 36, and also electrically coupled to the base power supply 32. The memory 37 is configured to store or record a log of activity related with each sensor module 20 and its respective ground clamp 10. Such activity can include the credentials or identity of the user who has accessed or caused a change in the status of the ground clamp 10. Such activity can also include a log of the locations of the ground clamp 10, whether the ground clamp 10 is connected to a piece of equipment or not, which piece of equipment the ground clamp 10 was installed on, which operator installed the ground clamp 10 onto the piece of equipment, or any other suitable or desirable activity can be logged and stored in memory 37. Memory 37 can also be configured to keep a running log of all activity related to a specific ground clamp 10, including activity that is not relatively recent for record keeping and auditing purposes. Such information can aid in loss prevention and asset recovery operations as well as troubleshooting and root-cause failure analyses by providing detailed user, use, location, or any other information capable of being stored in memory 37 for a particular ground clamp 10. The external communications module 36 can also be configured to update the external server or external device 14 with the log of activity stored or recorded in memory 37. In some implementations, memory 37 is configured to upload or update the external server with all of the data stored thereon when memory 37 has almost reached its data storage capacity and then purge the data stored locally on memory 37. For such implementations, the action of purging data presently stored on memory 37 ensures that there is capacity to store new updates to activity.

with continued reference to FIG. 5, the base power supply 32 is electrically coupled or otherwise configured to provide electrical power to the local communications module 34, the external communications module 36, and memory 37. The base power supply 32 is either directly connected to an external consistent power supply or is a standalone battery. In embodiments where the base power supply 32 is a battery, the batteries can be standard batteries of any suitable size such as, AA batteries, AAA batteries, cordless tool batteries, or any other suitable battery size. In other embodiments, the base power supply 32 is electrically coupled to an external battery charger or other power source such as a solar panel to ensure that the base power supply 32 of the base communications module 30 does not prematurely run out of power.

In many embodiments, the base member 28 can be disconnected or uncoupled from the central communications module 30. In such embodiments, the central communications module 30 can be placed on a stable surface such as a table or other suitable support structure.

In some embodiments, the base station 12 can include a display that is configured to display the status of the various ground clamps 10 or data gathered by or sensed by sensor 24 of a particular ground clamp. In such embodiments, the display can be configured to depict a list of the status of all ground clamps 10 associated with the base station 12. However, alternative embodiments are also envisioned, for example, the display of the base station 12 can also be configured to show the status of only a single ground clamp 10 at one time while also showing more detailed information about the specific ground clamp 10. Such detailed information can include when the ground clamp 10 was placed in service, when the ground clamp 10 was last moved, what was the last recorded data for the sensor 24 of the ground clamp 10, and any other set or subset of information that the operator may deem suitable.

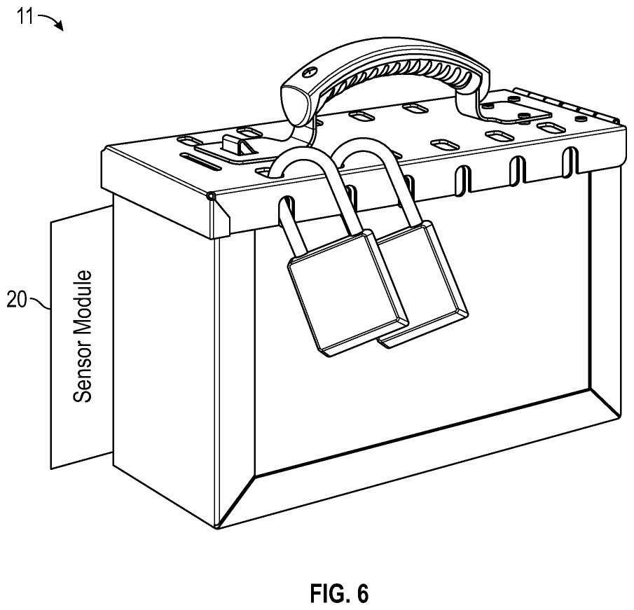

Reference is now made to FIG. 6, which depicts a front side perspective view of an embodiment of a lock box 11 shown in FIG. 1. A lock box 11 includes a sensor module 20 as described above and throughout this disclosure. The lock box 11 can have the sensor module 20 fully integrated into a structural side or component of the lock box 11. The lock box 11 can also be a common lock box 11 with the sensor module 20 retrofitted to the lock box 11. In such embodiments that utilize a lock box 11 in the system 100, the lock box 11 can aid in expanding the geographic scope of the mesh network, aid in strengthening the mesh network, or both by acting as another point that can receive and transmit messages from surrounding sensor modules 20. The status of the lock box 11 can be whether the lock box 11 is locked, unlocked, open, closed, or any other suitable status. The lock box 11 is otherwise configured to function as a standard lock out tag out (“LOTO”) box with a master key stored in the interior of the lock box 11 and points for workers to hang or affix personal locks, work-group locks, or any other suitable lock on the exterior of the lock box 11 such that the lock box 11 cannot be opened to access the master lock without the removal of the exterior locks thereon. From the base station 12 or external device 14, a user can request that the sensor module 20 of the lock box 11 (or ground clamp 10) update its status such that the user can see the present status of the lock box 11.

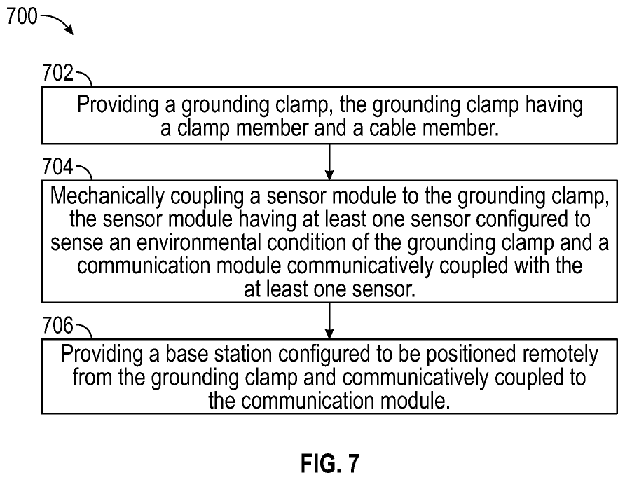

Reference is now made to FIG. 7, which depicts a block flow diagram of a method 700 of manufacturing a ground clamp monitoring system 100. The method 700 includes step 702, providing a grounding clamp, the grounding clamp having a clamp member and a cable member. The method 700 further includes step 704, mechanically coupling a sensor module to the grounding clamp, the sensor module having at least one sensor configured to sense an environmental condition of the grounding clamp and a communication module communicatively coupled with the at least one sensor. The method 700 finally includes step 706, providing a base station configured to be positioned remotely from the grounding clamp and communicatively coupled to the communication module.

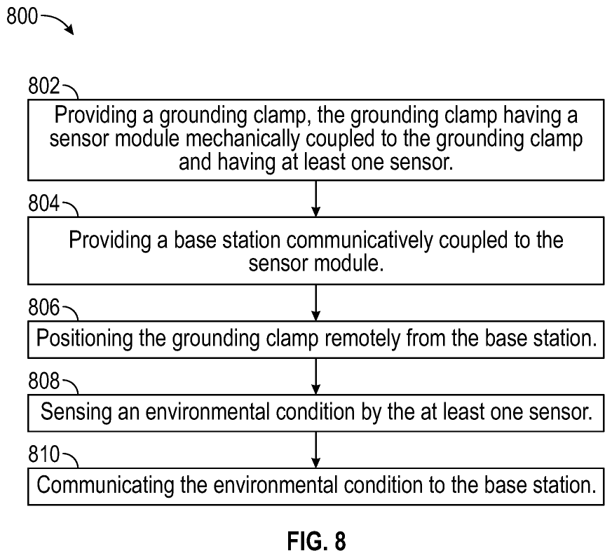

Reference is now made to FIG. 8, which depicts a block flow diagram of a method 800 of operating a ground clamp monitoring system 800. The method includes step 802, providing a grounding clamp, the grounding clamp having a sensor module mechanically coupled to the grounding clamp and having at least one sensor. The method 800 further includes step 804, providing a base station communicatively coupled to the sensor module. The method 800 further includes step 806, positioning the grounding clamp remotely from the base station. The method 800 further includes step 808, sensing an environmental condition by the at least one sensor. The method 800 further includes step 810, communicating the environmental condition to the base station.

Although embodiments of a ground clamp monitoring system 100 apparatus and method have been described in detail, those skilled in the art will also recognize that various substitutions and modifications may be made without departing from the scope and spirit of the appended claims.

In the foregoing description of certain embodiments, specific terminology has been resorted to for the sake of clarity. However, the disclosure is not intended to be limited to the specific terms so selected, and it is to be understood that each specific term includes other technical equivalents which operate in a similar manner to accomplish a similar technical purpose. Terms such as “left” and “right,” “front” and “rear,” “above” and “below” and the like are used as words of convenience to provide reference points and are not to be construed as limiting terms.

In this specification, the word “comprising” is to be understood in its “open” sense, that is, in the sense of “including,” and thus not limited to its “closed” sense, that is the sense of “consisting only of.” A corresponding meaning is to be attributed to the corresponding words “comprise,” “comprised” and “comprises” where they appear.

In addition, the foregoing describes some embodiments of the disclosure, and alterations, modifications, additions and/or changes can be made thereto without departing from the scope and spirit of the disclosed embodiments, the embodiments being illustrative and not restrictive.

Furthermore, the disclosure is not to be limited to the illustrated implementations, but to the contrary, is intended to cover various modifications and equivalent arrangements included within the spirit and scope of the disclosure. Also, the various embodiments described above may be implemented in conjunction with other embodiments, e.g., aspects of one embodiment may be combined with aspects of another embodiment to realize yet other embodiments. Further, each independent feature or component of any given assembly may constitute an additional embodiment.

What is claimed is:

1. A smart grounding clamp system comprising:
a grounding clamp, the grounding clamp having a clamp member and a cable member;
a sensor module mechanically coupled to the grounding clamp and having at least one sensor configured to sense an environmental condition of the grounding clamp and a communication module communicatively coupled with the at least one sensor; and
a base station positioned remotely from the grounding clamp and communicatively coupled to the communication module.

2. The smart grounding clamp system of claim 1, wherein the at least one sensor is an accelerometer configured to sense a change in a position of the grounding clamp.

3. The smart grounding clamp system of claim 1, wherein the at least one sensor is a partial discharge sensor.

4. The smart grounding clamp system of claim 1, wherein the at least one sensor is an infrared sensor configured to sense a movement.

5. The smart grounding clamp system of claim 4, further comprising a camera sensor configured to capture at least one photograph in response to the infrared sensor sensing the movement.

6. The smart grounding clamp system of claim 5, further comprising a storage module communicatively coupled to the camera sensor and is configured to store the at least one photograph captured by the camera sensor.

7. The smart grounding clamp system of claim 1, wherein the base station further includes an external communication module configured communicate with an external device.

8. The smart grounding clamp system of claim 1, wherein the grounding clamp is a plurality of grounding clamps and the communication module of a first grounding clamp of the plurality of grounding clamps can communicate with the communication module of a second grounding clamp of the plurality of grounding clamps.

9. The smart grounding clamp system of claim 1, wherein the communication module is further configured to communicate with an external device.

10. The smart grounding clamp system of claim 1, wherein the base station further includes a display configured to display a status of the grounding clamp.

11. A smart grounding clamp system comprising:
a plurality of grounding clamps, the plurality of grounding clamps each having at least one clamp member and a cable member;
a sensor module mechanically coupled to the at least one clamp member and having at least one sensor, a communication module communicatively coupled with the at least one sensor, and a power module configured to provide power to the at least one sensor and the communications module; and
a base station positioned remotely from the plurality of grounding clamps and communicatively coupled to each of the communication modules of the plurality of grounding clamps.

12. The smart grounding clamp system of claim 11, wherein the power module is a replaceable battery.

13. The smart grounding clamp system of claim 11, wherein the sensor module is positioned within a waterproof enclosure.

14. The smart grounding clamp system of claim 11, wherein the at least one sensor is an accelerometer configured to sense a change in a position of the respective grounding clamp.

15. The smart grounding clamp system of claim 11, wherein the at least one sensor is an infrared sensor configured to sense a movement near the infrared sensor.

16. The smart grounding clamp system of claim 11, wherein the at least one sensor is a partial discharge sensor.

17. A method of manufacturing a smart grounding clamp system, the method comprising:
providing a grounding clamp, the grounding clamp having a clamp member and a cable member;
mechanically coupling a sensor module to the grounding clamp, the sensor module having at least one sensor configured to sense an environmental condition of the grounding clamp and a communication module communicatively coupled with the at least one sensor; and
providing a base station configured to be positioned remotely from the grounding clamp and communicatively coupled to the communication module.

18. The method of claim 17, wherein the at least one sensor is an accelerometer configured to sense a change in a position of the grounding clamp.

19. The method of claim 17, wherein the at least one sensor is an infrared sensor configured to sense a movement near the infrared sensor.

20. The method of claim 17, wherein the at least one sensor is a partial discharge sensor.
